(19) United States
(12) Patent Application Publication
(10) Pub. No.: US 2020/0098698 A1
(43) Pub. Date: Mar. 26, 2020

(54) NOVEL WAFER LEVEL CHIP SCALE PACKAGE (WLCSP), FLIP-CHIP CHIP SCALE PACKAGE (FCCSP), AND FAN OUT SHIELDING CONCEPTS

(71) Applicant: Intel Corporation, Santa Clara, CA (US)

(72) Inventors: Richard PATTEN, Langquaid (DE); David O'SULLIVAN, Munich (DE); Georg SEIDEMANN, Landshut (DE); Bernd WAIDHAS, Pettendorf (DE)

(21) Appl. No.: 16/143,212

(22) Filed: Sep. 26, 2018

(51) Int. Cl. H01L 23/552; H01L 23/31; H01L 23/522

(52) U.S. Cl. CPC H01L 23/552; H01L 23/5226; H01L 23/3128; H01L 23/3114

(57) ABSTRACT

Embodiments include semiconductor packages, such as wafer level chip scale packages (WLCSPs), flip chip chip scale packages (FCCSPs), and fan out packages. The WLCSP includes a first doped region on a second doped region, a dielectric on a redistribution layer, where the dielectric is between the redistribution layer and doped regions. The WLCSP also includes a shield over the doped regions, the dielectric, and the redistribution layer, where the shield includes a plurality of surfaces, and at least one of the plurality of surfaces of the shield is on a top surface of the first doped region. The WLCSP may have interconnects coupled to the second doped region and redistribution layer. The shield may be a conductive shield that is coupled to ground, and the shield may be directly coupled to the redistribution layer and first doped region. The first and second doped regions may include highly doped n-type materials.

### FIELD

Embodiments relate to packaging semiconductor devices. More particularly, the embodiments relate to a wafer level chip scale package (WLCSP) shielding, a flip-chip chip scale package (FCCSP) shielding, and a fan out package shielding for semiconductor devices.

### BACKGROUND

For the past several decades, the scaling of features in integrated circuits has been a driving force behind an ever-growing semiconductor industry. Scaling to smaller and smaller features enables increased densities of functional units on the limited real estate of semiconductor devices. For example, a wafer level chip scale package (WLCSP) is one of the smallest packages that is available in the existing semiconductor industry.

With increase in signal complexity and frequency, WLCSPs may use shielding to improve the performance of these key factors. Moreover, the effectiveness of the shielding is becoming more and more important for system functionality and stability. Shielding is evolving from a global solution on mobile devices to a custom electronic solution per semiconductor device.

For semiconductor devices, space and performance at higher frequencies are leading differentiators of emerging communications networks. Additionally, these semiconductor devices are typically limited in footprint and z-height reduction. Shielding, however, is typically implemented on semiconductor devices using generic metal cages, metal plates, and grounding plates, thereby increasing the overall footprint and z-height and also impeding the performance at higher frequencies.

Some existing solutions include custom designed global metal shielding attached to the board of the device, or metals cans applied to the finished packages. These solutions typically have larger footprints, and thus limit the shrinkage of the overall electronic system and the placement of the device on the board. Additionally, these existing solutions are also tailored to be adapted/fitted on the worst performing electronic part on the board, which requires additional materials, limits design flexibility, and increases overall costs.

### BRIEF DESCRIPTION OF THE DRAWINGS

Embodiments described herein illustrated by way of example and not limitation in the figures of the accompanying drawings, in which like references indicate similar features. Furthermore, some conventional details have been omitted so as not to obscure from the inventive concepts described herein.

FIG. 1 is an illustration of a cross-sectional view of a wafer level chip scale package (WLCSP) having a shield, a plurality of doped regions, a plurality of interconnects, a dielectric, and a redistribution layer, according to one embodiment.

FIG. 2 is an illustration of a cross-sectional view of a flip-chip chip scale package (FCCSP) having a shield, a mold layer, an exposed die, and a substrate, where the shield is coupled to the exposed die with a plurality of interconnects, according to one embodiment.

FIG. 3 is an illustration of a cross-sectional view of a FCCSP having a shield, a mold layer, an exposed die, and a substrate, where the shield is coupled to a surface of the exposed die, according to one embodiment.

FIG. 4 is an illustration of a cross-sectional view of a fan out package having a shield, a mold layer, a die, a plurality of vias, and a redistribution layer, where the shield is coupled to the plurality of vias, according to one embodiment.

FIG. 5A is an illustration of a cross-sectional view of a fan out package having a plurality of dies, a mold layer, a via, and a plurality of redistribution layers, according to one embodiment.

FIG. 5B is an enlarged illustration of the cross-sectional view of the fan out package that illustrates the via embedded in the mold layer and disposed between the plurality of dies, according to one embodiment.

FIG. 6 is an illustration of a plan view of a fan out package having a plurality of dies, a mold layer, a plurality of vias, and a plurality of redistribution layer interconnects, according to one embodiment.

FIG. 7 is an illustration of a cross-sectional view of a semiconductor packaged system including a die, a substrate, a package substrate, and one or more semiconductor packages, according to one embodiment.

FIG. 8 is an illustration of a schematic block diagram illustrating a computer system that utilizes a semiconductor package having a shield surrounding a plurality of doped regions, a plurality of interconnects, a dielectric, and a redistribution layer, according to one embodiment.

### DETAILED DESCRIPTION

Described herein are semiconductor packages, such as a wafer level chip scale package (WLCSP), a flip-chip chip scale package (FCCSP), and a fan out package, having conductive shielding and methods of forming such semiconductor packages. The semiconductor packages described below and methods of forming such semiconductor packages include a grounded shield disposed on and surrounding the WLCSPs/FCCSPs, which enables the grounded shield to be coupled via backside connections to a highly doped backside region of a wafer (or a wafer die). Additionally, the semiconductor packages described below and methods of forming such semiconductor packages include a grounded shield disposed on and surrounding the fan out packages, which enables the grounded shield to be coupled via sidewall connections to vias (e.g., half-depth vias, conductive plugs, etc.) or trenches.

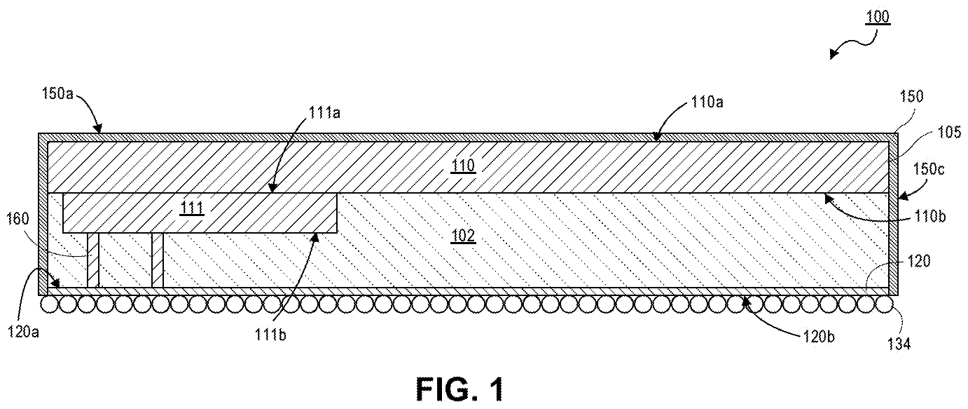

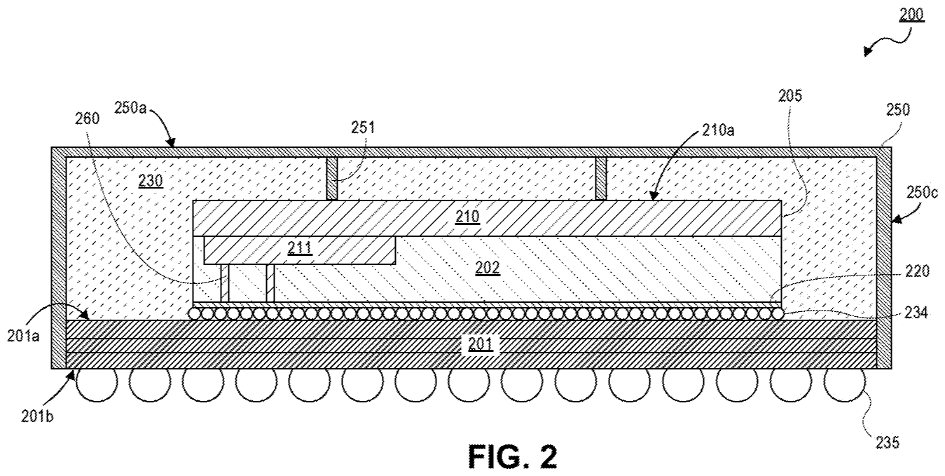

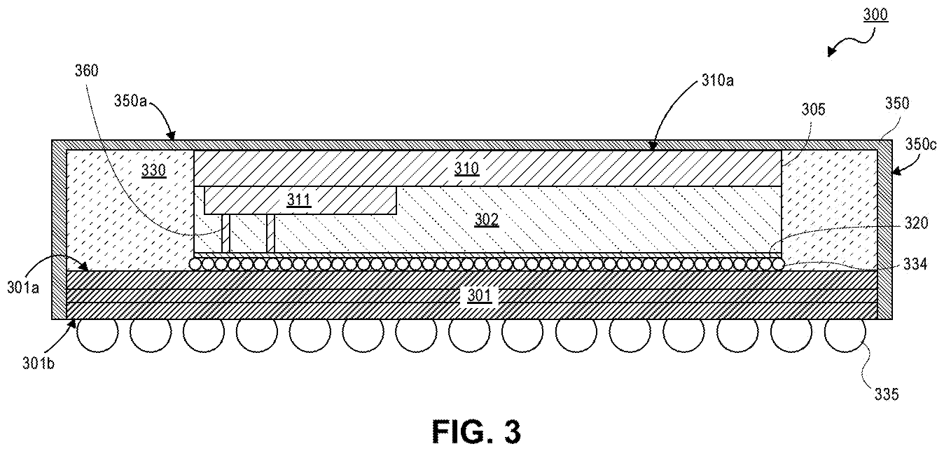

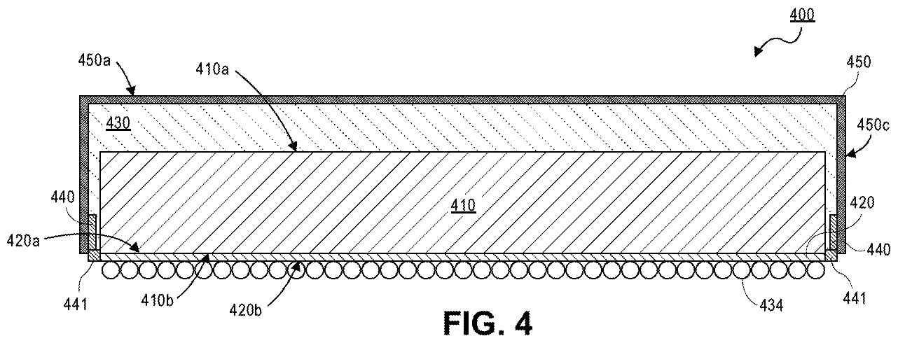

According to some embodiments, a semiconductor package is described (e.g., the WLCSP 100 shown in FIG. 1, the FCCSPs 200 and 300 shown in FIGS. 2-3, and the fan out package 400 shown in FIG. 4). For one embodiment, the WLCSP includes a first doped region (e.g., a wafer die, a highly doped n-type area/region, etc.) disposed on (or over) a second doped region (e.g., as shown with the first and second doped regions 110-111 of FIG. 1). In some embodiments, the first and second doped regions have a plurality of sidewalls, a top surface, and a bottom surface that is opposite to the top surface. For example, in one embodiment, the bottom surface of the first doped region is disposed on the top surface of the second doped region, and the first doped region has four sidewalls and the top surface exposed—prior to disposing a shield on the package.

For some embodiments, the WLCSP includes a dielectric (or a silicon bulk) disposed on a redistribution layer (e.g., an active area, a conductive layer, etc.), as such the dielectric is thus disposed between the redistribution layer, the bottom surface of the first doped region, and the bottom surface and sidewalls of the second doped region (e.g., as shown with the dielectric 102, the redistribution layer 120, and the doped regions 110-111 of FIG. 1). According to some embodiments, the WLCSP includes a shield (e.g., a 5-sided ground shield) surrounds the first and second doped regions, the dielectric, and the redistribution layer, wherein the shield is coupled to the redistribution layer and the top surface and the plurality of sidewalls of the first doped region (e.g., as shown with the shield 150 surrounding the top surface and four sidewalls of the die 110 of FIG. 1).

In one embodiment, the WLCSP may also include a plurality of interconnects (e.g., a deep-end dry well) that are used to couple the second doped region and the redistribution layer (e.g., as shown with the interconnects 160 of FIG. 1). For one embodiment, the shield is a conductive ground shield that may be directly coupled to the top surface of the first doped region and the redistribution layer. In another embodiment, the WLCSP may further include a plurality of solder balls coupled to the redistribution layer. For some embodiments, the first and second doped regions may include a plurality of highly doped n-type materials (e.g., implanted N++ regions/areas). In one embodiment, the shield is a five-sided shield that may include a top surface and four sidewalls.

As used herein, a “shield” (also referred to as conductive shield or a conductive grounding shield) refers to a conductive enclosure such as a metal enclosure (e.g., the metal enclosure may be an open-ended enclosure having 5-sides and an open bottom side). The “shield” described herein may be used to suppress (or shield off) electromagnetic interference (EMI), radio frequency interference (RFI), and/or any other interference to the surrounding components of the semiconductor packages (e.g., the WLCSP 100 of FIG. 1, the FCCSPs 200 and 300 of FIGS. 2-3, and the fan out packages 400, 500, and 600 of FIGS. 4-6). The “shield” may mitigate high-frequency regulatory violations and wireless performance degradation. The “shield” described herein improves the overall space and performance at higher frequencies of the semiconductor packages. Additionally, the “shield” described herein improves packaging solutions by reducing the overall footprint and z-height of the semiconductor packages.

Embodiments of the semiconductor packages enable a conformal shielding (or a 5-sided grounded adaptable conformal shield) to be disposed on a WLCSP/FCCSP device, which thus surrounds the WLCSP/FCCSP device on all 5-sides (as the bottom side may be closed-off by the redistribution layer). Additional embodiments of the semiconductor packages allow the conductive shield to conform to any shape and include one or more sides (i.e., the shield is not limited to 5-sides). Other embodiments of the semiconductor packages help to implement conformal shielding on a fan out package device with integrated, for example, silicon grounding. The embodiments of the shielding improve the space and high frequency performances of the semiconductor packages. Additionally, the embodiments of the WLCSP and FCCSP improve shielding concepts/techniques by directly coupling the conductive shield to the highly doped regions/areas in the silicon and the grounded network of the redistribution layer.

Some additional advantages of the embodiments described herein include enabling the starting silicon to be purchased with the shielded areas (e.g., the shield, the interconnects, etc.) already implemented on the semiconductor packages, or to be integrated with the necessary regions during processing. For example, one of the advantages of the semiconductor packages is that the conformal shielding with may be integrated as a grounding technique that may be utilized during the package's construction phase. Additionally, some other advantages of the embodiments described herein include: (i) a decreased footprint at the substrate (or the printed circuit board (PCB)) level; (ii) a lowered cost for the overall system (i.e., a cost-efficient process flow); and (iii) an improved conformal shielding that may be used on various semiconductor packages (such as at the wafer level with the WLCSPs) to integrate grounding techniques, which may improve the overall electric performances at higher frequencies and be integrated during package manufacture using, for example, a standard assembly processes resulting in a smaller global PCB footprint compared to the existing solutions (e.g., lids, shielding frames, cages, etc.).

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages (e.g., WLCSPs, FCCSPs, and fan out packages) having a conductive ground shield to surround a device (e.g., a wafer die), a mold layer, one or more interconnects, and/or a package substrate, where the conductive shield may also be coupled to one or more vias, plugs, pillars, and/or trenches disposed on the sides/edges of the package substrate and in between one or more dies.

In the following description, various aspects of the illustrative implementations will be described using terms commonly employed by those skilled in the art to convey the substance of their work to others skilled in the art. However, it will be apparent to those skilled in the art that the present embodiments may be practiced with only some of the described aspects. For purposes of explanation, specific numbers, materials and configurations are set forth in order to provide a thorough understanding of the illustrative implementations. However, it will be apparent to one skilled in the art that the present embodiments may be practiced without the specific details. In other instances, well-known features are omitted or simplified in order not to obscure the illustrative implementations.

Various operations will be described as multiple discrete operations, in turn, in a manner that is most helpful in understanding the present embodiments, however, the order of description should not be construed to imply that these operations are necessarily order dependent. In particular, these operations need not be performed in the order of presentation.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

FIG. 1 is an illustration of a cross-sectional view of a WLCSP 100 having a shield 150 surrounding a plurality of doped regions 110-111, a plurality of interconnects 160, a dielectric 102, and a redistribution layer 120, according to one embodiment. Furthermore, FIG. 1 illustrates the WLCSP 100 having the shield 150 disposed over a WLCSP device 105 that may have one or more different doping levels (e.g., a first doped region 110 and a second doped region 111). For example, the WLCSP device 105 has the first and second doped regions 110-111, where each of the doped regions 110-111 may be a heavily/highly doped N++ region. In some embodiments, the first doped region 110 may extend over the entire non-active side of the silicon area of the WLCSP device 105. Moreover, in another embodiment, the first doped region 110 may be disposed on/above the second doped region 111, where the second doped region 111 is conductively coupled/connected to the redistribution 120 layer using a plurality of conductive vias 160 (or a plurality of highly doped (N++) implants), and where the redistribution layer 120 is then conductively coupled and disposed on/over a plurality of solder balls 134 (or a plurality of mechanical interconnects).

In particular, for some embodiments, FIG. 1 illustrates the WLCSP 100 having the shield 150 disposed (or sputtered) on a WLCSP device 105 (may also be referred to as an integrated circuit (IC) die/device, a WLCSP die, an exposed WLCSP, and/or an exposed die), where the WLCSP device 105 includes the first and second doped regions 110-111, the interconnects 160, the dielectric 102, and/or the redistribution layer 120. Note that, in some embodiments, the WLCSP device 105 may be one WLCSP device that has been singulated (or diced)—at the wafer level—from a plurality of other WLCSP devices contained within in a wafer. For example, the wafer may be any suitable type of wafer such as a bulk silicon wafer, a silicon-on-insulator (SOI) wafer, an engineered substrate formed of one or more semiconductor materials (e.g., crystalline silicon, amorphous silicon, polysilicon, etc.), and/or the like. In addition, for some embodiments, the wafer may be full or ground down to a predetermined substrate thickness.

According to some embodiments, the WLCSP 100 includes a first doped region 110 that is disposed on a second doped region 111. The first and second doped regions 110-111 may be a silicon die, a wafer die, a highly doped area/region (e.g., an N++ type doped silicon area/region), and/or the like. The first and second doped regions 110-111 may be formed from one or more materials such as silicon and have circuitry thereon that may be coupled to another die, for example, the first doped region 110 coupled to the second doped region 111, and/or another substrate, for example, the first doped region 110 and/or the second doped region 111 coupled to the redistribution layer 120.

In one embodiment, the first and second doped regions 110-111 are formed from a plurality of highly doped n-type materials, such as one or more dopants used for n-type silicon including phosphorus, arsenic, and/or the like. In other embodiments, the first and second doped regions 110-111 may include, but are not limited to, a semiconductor die, a package (e.g., a carrier wafer package), an electronic device (e.g., a wireless device), an IC, a central processing unit (CPU), a microprocessor, a platform controller hub (PCH), a memory, and a field-programmable gate array (FPGA).

For one embodiment, the redistribution layer 120 may include one or more conductive layers stacked on top of each other. In other embodiments, the redistribution layer 120 may be disposed on the WLCSP device 105 to couple the first and second doped regions 110-111 to another substrate by using a plurality of solder balls 134. In one embodiment, the redistribution layer 120 may be formed by sputtering (or disposing/depositing) a conformal conductive layer, such as a layer of Cu, Ni, Sn, Au, Ag, Al, an Al alloy, W, Ti, Ta, TiN, TaN, or the like, using any suitable method, including evaporation, sputter, electroplating, printing, jetting, stud bumping, direct placement, or the like.

The first and second doped regions 110-111 may have a plurality of sidewalls, a top surface, and a bottom surface that is opposite to the top surface. In one embodiment, the first and second doped regions 110-111 may have a rectangular shape (i.e., 6-sides), but in other embodiments, the first and second doped regions 110-111 may have any shape based on the desired packaging design. For some embodiments, a bottom surface 110b of the first doped region 110 may be disposed (or stacked) on a top surface 111a of the second doped region 111, where the first doped region 110 may have a footprint that greater than a footprint of the second doped region 111. In other embodiments, however, the first doped region 110 and the second doped region 111 may have approximately the same footprint. Note, as used herein, a “footprint” refers to an area in the x-y dimensions that may define a die. For one embodiment, after the doped regions 110-111 are stacked, the first doped region 110 may have four sidewalls and a top surface 110a that may be exposed—where the exposed top surface 110a and sidewalls are subsequently enclosed by the shield 150 as shown in FIG. 1.

For some embodiments, the WLCSP 100 also includes the dielectric 102 that is disposed between the doped regions 110-111 and the redistribution layer 120. For example, the dielectric 102 may be disposed between a top surface 120a of the redistribution layer 120, a bottom surface 110b of the first doped region 110, and a bottom surface 111b (and/or sidewalls) of the second doped region 111.

In one embodiment, the dielectric 102 may be silicon bulk, one or more an interlayer dielectrics (ILDs), and/or any suitable insulating layer. For one embodiment, the dielectric 102 may be a polymer material such as, for example, polyimide, epoxy, or build-up film (BF). For one embodiment, the dielectric 102 may be an ajinomoto build-up film (ABF). In an embodiment, the dielectric 102 may be one layer in a stack of layers that includes a plurality of additional dielectrics used to form a build-up structure. As such, by way of example, the dielectric 102 may be formed over another dielectric. Additional embodiments may include disposing (or laminating) the dielectric 102 as a base dielectric over a core material (e.g., a glass carrier or the like) on which the stack is formed. According to an additional embodiment, the dielectric 102 may be the bottommost layer of the WLCSP 100 and may include, but is not limited to, a metallic material, an adhesive layer/film/tape, or any other core material.

The dielectric 102 may also include any appropriate dielectric material such as, but not limited to, an epoxy-polymer, a combination of epoxy-polymer materials, a silicon dioxide (Si0₂), and a silicon nitride. Additionally, the dielectric 102 may include a low-k dielectric and/or an ultra-low-k dielectric material having, but not limited to, one or more carbon doped dielectrics, fluorine doped dielectrics, porous dielectrics, organic polymeric dielectrics, silicon based polymeric dielectrics, and/or the like. As used herein, a “low-k dielectric” refers to a material having a lower dielectric constant (k) than silicon oxide. For example, the dielectric 102 may be formed using dielectric materials having low-k dielectric materials. Examples of such dielectric materials that may be used include, but are not limited to, Si0₂, carbon doped oxide (CDO), silicon nitride, organic polymers such as perfluorocyclobutane or polytetrafluoroethylene, fluorosilicate glass (FSG), and/or organosilicates, such as silsesquioxane, siloxane, or organosilicate glass.

According to some embodiments, as described above, the WLCSP 100 further includes the shield 150 which surrounds (or encloses) the first and second doped regions 110-111, the dielectric 102, and the redistribution layer 120. For some embodiments, the shield 150 may be a conductive shield (also referred to as a conductive grounding shield) which includes one or more conductive materials, such as copper, aluminum, gold, nickel, titanium, silver, stainless steel, a laminate conductive material, a combination thereof, and/or the like. In some embodiments, the shield 150 may be formed of one or more conductive layers stacked on top of each other, for example, stacking a first conductive layer of stainless steel, a second conductive layer of copper/nickel, and a third conductive layer of stainless steel on top of each other. For example, a sputtering tool (or the like) may be used to dispose (or add) a conductive coating, which includes the one or more conductive materials, on the exposed surfaces of the WLCSP 105 device (e.g., the exposed surfaces may include the top surface 110a of the first doped region; and the sidewalls of the first doped region 110, the dielectric 102, and the redistribution layer 120).

In some embodiments, the shield 150 may be a 5-sided conductive shield which includes the four sidewalls 150c and a top surface 150a. For example, in the illustrated embodiments, the sidewalls 150c of the shield 150 may be disposed on the dielectric 102 and coupled to the redistribution layer 120 and the first doped region 110; and the top surface 150a of the shield 150 may be disposed on and coupled to the top surface 110a of the first doped region 110 of the WLCSP device 105. For some embodiments, the shield 150 may have a thickness (or a z-height) of approximately 5 to 25 μm, and a length (or a width) of approximately 2 to 12 μm. In other embodiments, the shield 150 may have a thickness of approximately 25 μm or less, and a length (or width) approximately of 12 μm or less. In addition, in other embodiments, the shield 150 may have any shape (e.g., rectangular, open-enclosure, square, round, tapered, etc.) and may include one or more sides (i.e., the shield is not limited to 5-sides) based on the desired packaging design.

In one embodiment, the WLCSP 100 may also include a plurality of interconnects 160 that are coupled to the first and second doped regions 110-111 and the redistribution layer 120. For example, as in the illustrated embodiments, the interconnects 160 may be coupled to the top surface 120a of the redistribution layer 120 and the bottom surface 111b of the second doped region 111. In one embodiment, the interconnects 160 may be deep-end dry wells (also referred to as deep-high energy implants) that are formed through the dielectric 102, and then disposed with conductive material(s) to electrically couple the active side(s) of the first and second doped regions 110-111 to the redistribution layer 120. As used herein, an “active side” refers to a surface on an electrical component, such as a die and/or a substrate, which has one or more conductive materials and/or conductive components, such as any ICs or the like. For example, contact to the active side of the N++ region/area of the WLCSP device 105 may be implemented through the front of the wafer using the interconnects 160 (or deep high energy implants) and/or the like.

In another embodiment, the WLCSP 100 may further include a plurality of solder balls 134 disposed on and coupled to a bottom surface 120b of the redistribution layers 120. For some embodiments, after the shield 150 and the solder balls 134 are disposed, the WLCSP device 105 of the WLCSP 100 may then be disposed on another component, such as another substrate which may include a PCB, a package substrate, an interposer, and/or a motherboard.

Note that the WLCSP 100 may include fewer or additional packaging components based on the desired packaging design.

For additional embodiments, as described above, the WLCSP 100 may be formed with a wafer. The wafer may be reduced (or ground/etched) to a predefined thickness, physically separated using a standard singulating process (e.g., using a laser groove followed by dicing or stealth dicing) that separates the plurality of dies (or wafer dies) on the wafer, and then the separated dies may be mechanically arranged onto a predefined matrix on a carrier with the active side of the dies facing downwards. The shape of the matrix may be selected (or determined) by the subsequent assembly line capability, for example, the matrix may be round or in panel format. After the dies have been disposed on the matrix on the carrier, in one embodiment, a mold layer (or an encapsulation layer) may be disposed on the wafer to encapsulate (or embed) the dies (e.g., the first and second doped regions 110-111), while one or more surfaces of the die(s) is/are left unexposed (e.g., the active side of the die(s)). Note that disposing the mold layer may be optional and used based on the desired packaging design.

In some embodiments, a lithography process may then be implemented on the wafer (or the device) to dispose a base dielectric (or an initial dielectric layer) (e.g., the dielectric 102) to the panel on the active side of the dies. The dielectric may then be patterned to expose one or more openings and thus form one or more interconnects (e.g., the interconnects 160) within the dielectric (or silicon bulk) and/or the molded area. Furthermore, in other embodiments, a sputtering stage may then be implemented on the device (e.g., the WLCSP device 150) to dispose a thin coating of conductive material (e.g., a metal such as copper) over the active area/side of the wafer. For example, this thin coating of conductive material may then partially fill any openings (e.g., any via, interconnect, and/or trench) within the panel, and may then act as an adhesive layer on the mold layer for subsequent processes (if the mold layer is used).

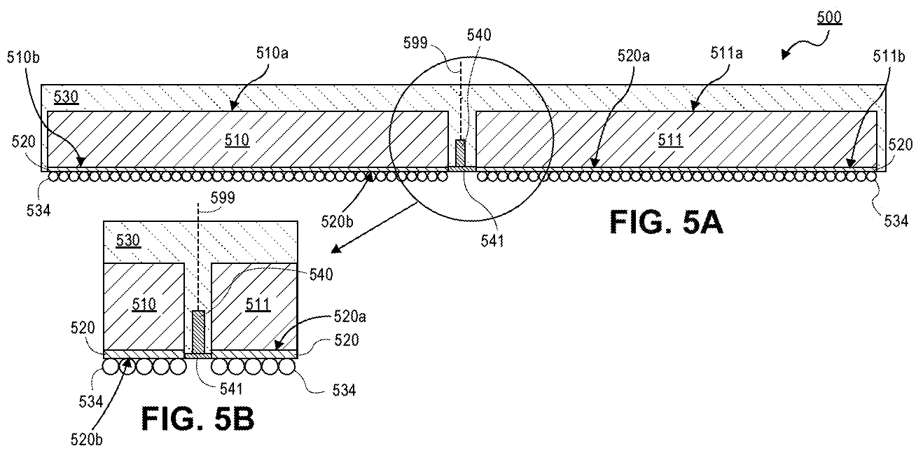

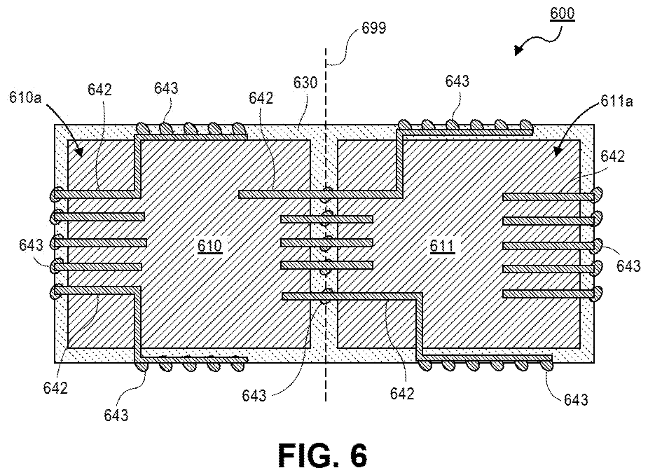

Additionally, a second lithography process may be implemented to define the redistribution layer (e.g., the redistribution layer 120) on the device and/or the molded area. For some embodiments, the design of the redistribution layer may include ground connections that are required for the shield—but may also be shared with adjacent devices (e.g., as shown in FIGS. 5-6). Subsequently, the device may then be disposed (or plated) with a conductive metal (e.g., copper or the like) on the outer periphery surfaces of the device to reach a desired uniform thickness. Likewise, if any previously etched mold vias/trenches are formed, these vias/trenches are also plated and filled during this process. The device may have a plating resist and a thin seed layer which may be removed/etched from the surface of the device. Note that the above process may be repeated several times depending on the number of redistribution layers required.

Note that it is also possible to initiate the above process flow used to form the WLCSP device—or any other semiconductor package described herein—with or without the above described molding process. Likewise, it is also possible to initiate the above process flow with the device (e.g., the WLCSP device, the FCCSP device, and/or the fan out package device) already having the redistribution layer, as such the process flow may be shortened to include (i) disposing the device with a conductive shield/layer to implement/finalize the grounded shielding technique described herein, and (ii) then exposing the landing pads of the redistribution layer for any subsequent electrical connection to the outside such as a solder ball, a conducting bump, or a copper pillar. Also note that additional embodiments and/or process flows are described below with one or more different components and/or steps as shown with FIG. 2-8.

FIG. 2 is an illustration of a cross-sectional view of a FCCSP 200 having a shield 250 surrounding (or enclosing) a mold layer 230, a device 205, and a package substrate 201, where the shield 250 is coupled to the device 205 with a plurality of interconnects 251 (or a plurality of second interconnects), according to one embodiment. The FCCSP 200 may be similar to the WLCSP 100 of FIG. 1, however the FCCSP 200 includes the shield 250 directly disposed on the mold layer 230 and coupled to a top surface 210a of a first doped region 210 of the device 205 using the interconnects 251 (or through mold vias (TMVs)). Note that the one or more components of the FCCSP 200 may be similar to the one or more components of the WLCSP 100 of FIG. 1 as described above.

In some embodiments, the FCCSP 200 may include the shield 250 disposed on the one or more exposed surfaces of the mold layer 230, where the mold layer 230 may be disposed on the device 205 (e.g., a WLCSP device, an IC die/device, or the like). As shown in FIG. 2, the device 205 device includes the first and second doped regions 210-211, the interconnects 260 (or the first interconnects), the dielectric 202, the redistribution layer 220, and/or the plurality of solder balls 234 (or a plurality of first solder balls). Note that the device 205 is similar to the WLCSP device 105 of FIG. 1 as described above, however the device 205 may be directly enclosed by the mold layer 230 and not the shield 250.

In some embodiment, the FCCSP 200 includes the mold layer 230 (also referred to as an encapsulation layer) disposed on and around the device 205, the solder balls 234, and the package substrate 201. For one embodiment, the mold layer 230 is made of an epoxy (e.g., a soft epoxy, a stiff epoxy, opaque epoxy, etc.) with one or more filler materials. According to some embodiments, the one or more materials for the mold layer 230 may include, but are not limited to, ultra-compliant materials for semiconductor devices, pressure sensors, visible light, ultraviolet (UV) and infrared (IR) absorbing/reflective materials to block photons from the dies, stiff polymers to encapsulate the interconnects and/or vias, and/or transparent materials.

For one embodiment, the device 205 may be disposed on and coupled on a top surface 201a of the package substrate 201. According to some embodiments, the package substrate 201 may include, but is not limited to, a package, a substrate, a PCB, and/or a motherboard. For one embodiment, the package substrate 201 is a PCB. For one embodiment, the PCB is made of an FR-4 glass epoxy base with thin copper foil laminated on both sides. For certain embodiments, a multilayer PCB can be used, with pre-preg and copper foil used to make additional layers. For example, the multilayer PCB may include one or more dielectric layers, where each dielectric layer can be a photosensitive dielectric layer. For some embodiments, holes may be drilled in the PCB 201. For one embodiment, the PCB 201 may also include conductive copper traces, metallic pads, and holes.

Additionally, as shown in the illustrated embodiments, the FCCSP 200 includes the interconnects 251 that are used to couple a top surface 250a of the shield 250 to the top surface 210a of the first doped region 210 of the device 205. In the one embodiment, the interconnects 251 may be through mold conductive contacts, vias, pillars, or the like (e.g., metal-plated contacts, vias, pillars, etc.). For one embodiment, the interconnects 251 of the FCCSP 200 may include one or more different interconnects, such as a via bar, a TMV, or a combination of two or more TMVs/via bars based on the desired packaging design. For one embodiment, the interconnects 251 may be disposed adjacent to each other and on the top surface of the device 205. For some embodiments, the interconnects 251 may have a thickness of approximately 100 to 400 μm. In other embodiments, the interconnects 251 may have a thickness of approximately 400 or less. For one embodiment, the interconnects 251 are disposed vertically through the mold layer 230, coupling the shield 250 to the top surface 210a of the first doped region 210. In some embodiments, the interconnects 251 may be formed using the one or more conductive materials (e.g., copper, aluminum, gold, titanium, silver, stainless steel, a laminate conductive material, a combination thereof, and/or the like) that are used to form the shield 250 as described herein.

According to some embodiments, the FCCSP 200 further includes the shield 250 that is disposed on the mold layer 230 and the substrate 201. The shield 250 may surround (or enclose) device 205, including the first and second doped regions 210-211, the dielectric 202, the interconnects 260, the redistribution layer 220, and the solder balls 234. For some embodiments, the shield 250 may be a conductive shield which includes one or more conductive materials, such as copper, aluminum, gold, nickel, titanium, silver, stainless steel, a laminate conductive material, a combination thereof, and/or the like. In some embodiments, the shield 250 may be formed of one or more conductive layers stacked on top of each other, for example, stacking a first conductive layer of stainless steel, a second conductive layer of copper/nickel, and a third conductive layer of stainless steel on top of each other. For example, a sputtering tool (or the like) may be used to dispose (or add) a conductive coating, which includes the one or more conductive materials, on the exposed surfaces of the mold layer 230 and the substrate 201 (e.g., the exposed surfaces may include the top surface and the sidewalls/edges of the mold layer 230; and the sidewalls/edges of the substrate 201).

In some embodiments, the shield 250 may be a 5-sided conductive shield which includes the four sidewalls 250c and the top surface 250a. For example, in the illustrated embodiments, the sidewalls 250c of the shield 250 may be disposed on the mold layer 230 and coupled to the package substrate 201, and the top surface 250a of the shield 250 may also be disposed on the mold layer 230 and coupled to the top surface 210a of the first doped region 210 of the device 205 with the interconnects 251. For some embodiments, the shield 250 may have a thickness of approximately 5 to 25 μm, and a length of approximately 2 to 12 μm. In other embodiments, the shield 250 may have a thickness of approximately 25 μm or less, and a length approximately of 12 μm or less. In addition, in other embodiments, the shield 250 may have any shape (as described above) and may include one or more sides (i.e., the shield is not limited to 5-sides) based on the desired packaging design.

For some embodiments, the FCCSP 200 may further include a plurality of solder balls 235 (or a plurality of second solder balls) that are disposed on and coupled to a bottom surface 201b of the package substrate 201. For example, the solder balls 235 may be used on a ball grid array (BGA). Note that other methods of connectivity packaging may also be used such as pin grid array (PGA) or land grid array (LGA). For some embodiments, after the shield 250 and the solder balls 235 are disposed, the FCCSP 200 may then be disposed on another component, such as another substrate which may include a PCB, a package substrate, an interposer, and/or a motherboard.

Note that the FCCSP 200 may include fewer or additional packaging components based on the desired packaging design.

FIG. 3 is an illustration of a cross-sectional view of a FCCSP 300 having a shield 350 surrounding (or enclosing) a mold layer 330, a device 305, and a package substrate 301, where the shield 350 may be directly disposed on and coupled to a top surface 310a of a first doped region 310 of the device 305, according to one embodiment. The FCCSP 300 may be similar to the WLCSP 100 of FIG. 1 and the FCCSP 200 of FIG. 2, however the FCCSP 300 has the shield 350 directly disposed on the top surface 310a of the first doped region 310 of the device 305. For example, the FCCSP 300 may expose the top surface 310a of the first doped region 310 by grinding/polishing (or during the mold process), accordingly the shield 350 may then be directly disposed on (or attached to) the exposed top surface 310a of the first doped region 310 (i.e., directly coupled to the N++ doped regions/areas) of the device 305. Note that the one or more components of the FCCSP 300 may be similar to the one or more components of the WLCSP 100 of FIG. 1 and the FCCSP 200 of FIG. 2 as described above.

In some embodiments, the FCCSP 300 may include the shield 350 disposed on the one or more exposed surfaces of the mold layer 330, where the mold layer 330 may be disposed on the device 305 (e.g., a WLCSP device, an IC die/device, or the like). As shown in FIG. 3, the device 305 includes the first and second doped regions 310-311, the interconnects 360, the dielectric 302, the redistribution layer 320, and/or the plurality of solder balls 334 (or the plurality of first solder balls). Note that the device 305 is similar to the WLCSP device 105 of FIG. 1 and the device 205 of FIG. 2 as described above, however the device 305 may be directly coupled to the shield 350 without needing any interconnects.

In some embodiment, the FCCSP 300 includes the mold layer 330 disposed on and around the device 305, the solder balls 334, and the package substrate 301. For one embodiment, the mold layer 330 is made of an epoxy (e.g., a soft epoxy, a stiff epoxy, opaque epoxy, etc.) with one or more filler materials. According to some embodiments, the one or more materials for the mold layer 230 may include, but are not limited to, ultra-compliant materials for semiconductor devices, pressure sensors, visible light, UV and IR absorbing/reflective materials to block photons from the dies, stiff polymers to encapsulate the interconnects and/or vias, and/or transparent materials.

For one embodiment, the device 305 may be disposed on and coupled on a top surface 301a of the package substrate 301. According to some embodiments, the package substrate 301 may include, but is not limited to, a package, a substrate, a PCB, and/or a motherboard. For one embodiment, the package substrate 301 is a PCB. For one embodiment, the PCB is made of an FR-4 glass epoxy base with thin copper foil laminated on both sides. For certain embodiments, a multilayer PCB can be used, with pre-preg and copper foil used to make additional layers. For example, the multilayer PCB may include one or more dielectric layers, where each dielectric layer can be a photosensitive dielectric layer. For some embodiments, holes may be drilled in the PCB 301. For one embodiment, the PCB 301 may also include conductive copper traces, metallic pads, and holes.

Additionally, as shown in the illustrated embodiments, the FCCSP 300 includes the shield 350 that is directly disposed on the mold layer 330, the device 305, and the substrate 301. The shield 350 may surround (or enclose) the device 305, including the first and second doped regions 310-311, the dielectric 302, the interconnects 360, the redistribution layer 320, and the solder balls 334. For some embodiments, the shield 350 may be a conductive shield that includes one or more conductive materials as described herein, and may be disposed directly on the exposed surfaces of the mold layer 330, the device 305, and the substrate 301 (e.g., the exposed surfaces may include a portion of the top surface of the mold layer 230, the top surface 310a of the first doped region 310 of the device 305, and the sidewalls/edges of the mold layer 330 and the substrate 301). In some embodiments, the shield 350 may be formed of one or more conductive layers stacked on top of each other, for example, stacking a first conductive layer of stainless steel, a second conductive layer of copper/nickel, and a third conductive layer of stainless steel on top of each other.

In some embodiments, the shield 350 may be a 5-sided conductive shield which includes the four sidewalls 350c and the top surface 350a. For example, in the illustrated embodiments, the sidewalls 350c of the shield 350 may be disposed on the mold layer 330 and coupled to the package substrate 301, and the top surface 350a of the shield 350 may also be disposed on the mold layer 330 and directly coupled to the top surface 310a of the first doped region 310 of the device 305. For some embodiments, the shield 350 may have a thickness of approximately 5 to 25 μm, and a length of approximately 2 to 12 μm. In other embodiments, the shield 350 may have a thickness of approximately 25 μm or less, and a length approximately of 12 μm or less. In addition, in other embodiments, the shield 350 may have any shape and may include one or more sides (i.e., the shield is not limited to 5-sides) based on the desired packaging design.

For some embodiments, the FCCSP 300 may further include a plurality of solder balls 335 (or a plurality of second solder balls) that are disposed on and coupled to a bottom surface 301b of the package substrate 301. For example, the solder balls 335 may be used on a BGA. Note that other methods of connectivity packaging may also be used such as PGA or LGA. For some embodiments, after the shield 350 and the solder balls 335 are disposed, the FCCSP 300 may then be disposed on another component, such as another substrate which may include a PCB, a package substrate, an interposer, and/or a motherboard.

Note that the FCCSP 300 may include fewer or additional packaging components based on the desired packaging design.

FIG. 4 is an illustration of a cross-sectional view of a fan out package 400 having a shield 450 surrounding (or enclosing) a mold layer 430, a die 410, a plurality of vias 440, and a redistribution layer 420, where the shield 450 may be disposed on the mold layer 430 and coupled to the vias 440, according to one embodiment. The fan out package 400 may be similar to the WLCSP 100 of FIG. 1 and the FCCSPs 200 and 300 of FIGS. 2-3, however the fan out package 400 has the sidewalls 450c of the shield 450 directly coupled to the vias 440 (also referred to as embedded conductive vias, trenches, and plugs). Note that the one or more components of the fan out package 400 may be similar to the one or more components of the WLCSP 100 of FIG. 1 and the FCCSPs 200 and 300 of FIGS. 2-3 as described above.

For some embodiments, the fan out package 400 includes disposing a bottom surface 410b of the die 410 on a top surface 420a of the redistribution layer 420. In additional embodiments, the fan out package 400 also includes disposing the mold layer 430 on a top surface 410a of the die 410 and one or more surfaces of the vias 440, where the vias 440 are coupled to a conductive layer 441 and the redistribution layer 420. According to some embodiments, the fan out package 400 further includes disposing a plurality of solder balls 434 on a bottom surface 420b of the redistribution layer 420.

In some embodiments, the fan out package 400 includes the die 410 which may be disposed on, for example, a carrier wafer (e.g., a round or a panel form carrier wafer) and initially shielded/enclosed by the mold layer 420. Additionally, for some embodiments, the fan out package 400 includes the vias 440 that may be disposed and shared between one or more dies (e.g., as shown in FIGS. 5A-5B) by using laser molding and plating (or Cu plating). In other embodiments, the vias 440 may be integrated into a redistribution layer (RDL) flow (or a plurality of RDL interconnects) if needed/desired (e.g., as shown in FIG. 6), which may increase the overall conductive area that is in contact (or coupled) with the shield 450.

As used herein, the “vias” refer to one or more conductive contacts (e.g., Cu contacts) such as conductive multi-plugs (also referred to as half-depth vias), conductive trenches, conductive pillars, and/or the like. For example, the “vias” may include multi-plugs or oblong shapes that are patterned (e.g., using a laser process, a drill process, and/or the like) in the mold layer (e.g., the mold layer 430) and then disposed (or plated) with one or more conductive materials to form the “vias”. In another example, the “vias” may include trenches that are lasered (or a similar process) along the mold layer and then disposed with one or more conductive materials to form the “vias”. In some embodiments, the vias 440 may have a depth that is not circular, but has a z-height that may be based on the lasering process (i.e., the vias may not have a circular shape, rather the vias may have an oval shape with an elongated trench as the z-height may be controlled by the patterning/lasering process).

For some embodiments, the fan out package 400 may implement the vias 440 to ensure a good electrical contact (or an increased electrical contact) to the shield 450, where the vias 440 may be formed deep within the mold layer 430, for example, as a half-via (i.e., a via that may be diced in half to form at least two half-vias, where a half-via may thus have a semi-circular shape and use the flat surface of the half-via to couple directly with the shield), a trench, a pillar, and/or the like. In some embodiments, the vias 440 may be formed by a laser process, or by implementing (or adding) a mask process to protect the die 410 and then selectively etching the required structures within the mold layer 430. As shown in FIG. 4, the vias 440 may also be coupled to a conductive layer 441 (or one or more portions of a conductive layer) that are used to conductively couple the vias 440 to the redistribution layer 420. For example, the shield 450 may be directly coupled to the vias 440, the conductive layer 441, and the redistribution layer 420.

For some embodiments, the vias 440 and the conductive layer 441 may be formed of one or more conductive materials, such as Cu, Ni, Sn, Au, Ag, Al, an Al alloy, W, Ti, Ta, TiN, TaN, and/or the like. Note that the vias 440 and the conductive layer 441 may be a single, continuous conductive component, or two or more separate, coupled conductive components. For some embodiments, the vias 440 may have a thickness/depth of approximately 20 to 30 and a length (or width) of approximately 45 (+/−5) to 80 (+/−5) In other embodiments, the vias 440 may have a thickness/depth of approximately 20 μm or less, and a length (or width) of approximately 80 μm or less. Note that, in alternate embodiments, the vias 440 may have any desired thickness and length based on the desired packaging design.

According to some embodiments, the die 410 may include, but is not limited to, a semiconductor die (or a silicon die), an IC, a CPU, and a microprocessor. For several embodiments, the die 410 may be formed of one or more semiconductor components/devices. In one embodiment, the die 410 may have a thickness of approximately 50 to 150 μm; or, in other embodiments, the die 410 may have a thickness of approximately 50 μm or less. Note that, according to alternate embodiments, the die 410 does not require an active semiconductor component/device, rather the die 410 may be formed of an organic substrate layer, a passive device (e.g., decoupling capacitors/power delivery inductors, antennas), micro-electromechanical systems (MEMS), and/or any other type of electronic component and/or sensor.

In some embodiment, the fan out package 400 includes the mold layer 430 disposed on and around the die 410, the vias 440, and the conductive layer 441, where the mold layer 430 is disposed on one or more surfaces of the vias 440—but at least one surface (e.g., the outer sidewall, the outer edge surface, etc.) is exposed. Note that, in one embodiment, the mold layer 430 may be disposed on a portion (or surface) of the redistribution layer 420. For one embodiment, the mold layer 430 is made of an epoxy (e.g., a soft epoxy, a stiff epoxy, opaque epoxy, etc.) with one or more filler materials. According to some embodiments, the one or more materials for the mold layer 430 may include, but are not limited to, ultra-compliant materials for semiconductor devices, pressure sensors, visible light, UV and IR absorbing/reflective materials to block photons from the dies, stiff polymers to encapsulate the interconnects and/or vias, and/or transparent materials.

In some embodiments, the fan out package 400 may include the shield 450 disposed on the one or more exposed surfaces of the mold layer 430 and the exposed surfaces of the vias 440 (as described above), where the sidewalls 450c of the shield 450 are thus disposed adjacently to the vias 440 and coupled vertically to the exposed surfaces to vias 440. In additional embodiments, the shield 450 may be formed to extend vertically from the top surface 450a of the shield 450 to the bottom surface 420b of the redistribution layer 420 (i.e., the sidewalls 450c of the shield 450 may be disposed on and coupled to both the vias 440 and the conductive layer 441).

Additionally, as shown in the illustrated embodiments, the fan out package 400 includes the shield 450 that is directly disposed on the mold layer 430 and the vias 440. For some embodiments, the shield 450 may be a conductive shield that includes one or more conductive materials as described herein. For some embodiments, the shield 450 may be a conductive shield which includes one or more conductive materials, such as copper, aluminum, gold, nickel, titanium, silver, stainless steel, a laminate conductive material, a combination thereof, and/or the like. In some embodiments, the shield 450 may be formed of one or more conductive layers stacked on top of each other, for example, stacking a first conductive layer of stainless steel, a second conductive layer of copper/nickel, and a third conductive layer of stainless steel on top of each other. For example, a sputtering tool (or the like) may be used to dispose (or add) a conductive coating, which includes the one or more conductive materials, on the exposed surfaces of the mold layer 430 and the exposed surfaces of the vias 440 (e.g., the exposed surfaces may include the top surface and the sidewalls/edges of the mold layer 430; and the outer sidewalls/edges of the vias 440).

In some embodiments, the shield 450 may be a 5-sided conductive shield which includes the four sidewalls 450c and the top surface 450a. For example, in the illustrated embodiments, the sidewalls 450c of the shield 450 may be disposed on the mold layer 430 and the vias 440, and coupled to the vias 440 (note that the sidewalls 450c may also be coupled to the conductive layer 441); and the top surface 450a of the shield 450 may also be disposed on the mold layer 430 and above the top surface 410a of the die 410. For some embodiments, the shield 450 may have a thickness of approximately 5 to 25 μm, and a length of approximately 2 to 12 μm. In other embodiments, the shield 450 may have a thickness of approximately 25 μm or less, and a length approximately of 12 μm or less. In addition, in other embodiments, the shield 450 may have any shape and may include one or more sides (i.e., the shield is not limited to 5-sides) based on the desired packaging design.

For some embodiments, the fan out package 400 may further include a plurality of solder balls 434 that are disposed on and coupled to the bottom surface 420b of the redistribution layer 420. For example, the solder balls 434 may be used on a BGA. Note that other methods of connectivity packaging may also be used such as PGA or LGA. For some embodiments, after the shield 450 and the solder balls 435 are disposed, the fan out package 400 may then be disposed on another component, such as another substrate which may include a PCB, a package substrate, an interposer, and/or a motherboard.

Note that the fan out package 400 may include fewer or additional packaging components based on the desired packaging design.

FIG. 5A is an illustration of a cross-sectional view of a fan out package 500 having a plurality of dies 510-511, a mold layer 530, a via 540, and a plurality of redistribution layers 520, according to one embodiment. Additionally, FIG. 5B is an enlarged illustration of the cross-sectional view of the fan out package 500 showing the via 540 embedded in the mold layer 530 and disposed between the plurality of dies 510-511, according to one embodiment.

In some embodiments, the fan out package 500 includes disposing the mold layer 530 on and around the dies 510-511, the via 540, the conductive layer 541, and the redistribution layers 520, where the vias 540 and the conductive layer 541 are disposed between the two dies 510-511 and are coupled to the redistribution layers 520, according to one embodiment. The fan out package 500 may be similar to the WLCSP 100 of FIG. 1, the FCCSPs 200 and 300 of FIGS. 2-3, and the fan out package 400 of FIG. 4, however the fan out package 500 illustrates the embedded via 540 disposed and shared between the two dies 510-511—prior to (i) dicing the fan out package 500 into individual dies, where the individual dies may then include half-vias disposed on the edges of the individual dies, and (ii) disposing a shield to surround the individual dies and the respective components (e.g., the half-vias, the mold layer, the redistribution layer, and so on). Note that the one or more components of the fan out package 500 may be similar to the one or more components of the WLCSP 100 of FIG. 1, the FCCSPs 200 and 300 of FIGS. 2-3, and the fan out package 400 of FIG. 4 as described above.

For some embodiments, the fan out package 500 includes disposing the bottom surfaces 510b and 511b of the dies 510-511 on the top surfaces 520a of the redistribution layers 520, respectively. In additional embodiments, the fan out package 500 also includes disposing the mold layer 530 on the top surfaces 510a and 511a of the dies 510-511, the via 540, and the conductive layer 541, where the via 540 is coupled to the conductive layer 541 and the redistribution layers 520. According to some embodiments, the fan out package 500 further includes disposing a plurality of solder balls 534 on the bottom surface 520b of the redistribution layers 520.

In some embodiments, the fan out package 500 includes the dies 510-511 which may be disposed on, for example, a carrier wafer (e.g., a round or a panel form carrier wafer) and initially shielded/enclosed by the mold layer 530. Additionally, for some embodiments, the fan out package 500 includes the via 540 that may be disposed and shared between the dies 510-511 by using laser molding and plating (or Cu plating). In other embodiments, the via 540 may be integrated into a RDL flow if needed/desired (e.g., as shown in FIG. 6), which may increase the overall conductive area that is in contact with a subsequently disposed shield.

For some embodiments, the fan out package 500 may implement the via 540 to ensure improved coupling with the redistribution layers 520 and a subsequently disposed shield, where the via 540 may be formed deep within the mold layer 530 as a via, a plug, a pillar, and/or a trench. In subsequent embodiments, the via 540 may be diced on an interface 599 between, for example, the die 510 region and the die 511 region, accordingly cutting/dicing in half the via 540 and the conductive layer 541 (e.g., as shown with the half via 540 disposed on each side of the die 410). In an embodiment, the interface 599 may be an abrupt interface. In another embodiment, the interface 599 may be a graded interface. Note that the dicing of the via 540 enables a via to have at least one exposed surface which may be used to subsequently couple the exposed surface of the via 540 to the subsequently disposed shield (e.g., as shown in FIG. 4).

In some embodiments, the via 540 may be formed by a laser process, or by adding an additional mask process to protect the dies 510-511 and then selectively etching the required structures within the mold layer 530. As shown in FIGS. 5A-5B, the via 540 may also be coupled to the conductive layer 541 that are used to conductively couple the via 540 to the redistribution layers 520.

For some embodiments, the vias 540 and the conductive layer 541 may be formed of one or more conductive materials, such as Cu, Ni, Sn, Au, Ag, Al, an Al alloy, W, Ti, Ta, TiN, TaN, and/or the like. Note that the via 540 and the conductive layer 541 may be a single, continuous conductive component, or two or more separate, coupled conductive components. For some embodiments, the via 540 may have a thickness/depth of approximately 20 to 30 μm, and a length (or width) of approximately 45 (+/−5) to 80 (+/−5) μm. In other embodiments, the via 540 may have a thickness/depth of approximately 20 μm or less, and a length (or width) of approximately 80 μm or less. Note that, in alternate embodiments, the via 540 may have any desired thickness and length based on the desired packaging design.

According to some embodiments, the dies 510-511 may include, but is not limited to, a semiconductor die, an IC, a CPU, and a microprocessor. For several embodiments, the die 510 may be formed of one or more semiconductor components/devices. In one embodiment, the die 510 may have a thickness of approximately 50 to 150 μm; or, in other embodiments, the die 510 may have a thickness of approximately 50 μm or less. Note that, according to alternate embodiments, the die 510 does not require an active semiconductor component/device, rather the die 510 may be formed of an organic substrate layer, a passive device (e.g., decoupling capacitors/power delivery inductors, antennas), MEMS, and/or any other type of electronic component and/or sensor.

In some embodiment, the fan out package 500 includes the mold layer 530 disposed on and around the dies 510-511, the via 540, and the conductive layer 541, where the mold layer 530 is disposed on the via 540. Note that, in one embodiment, the mold layer 530 may be disposed on a portion of the redistribution layer 520. For one embodiment, the mold layer 530 is made of an epoxy with one or more filler materials. According to some embodiments, the one or more materials for the mold layer 530 may include, but are not limited to, ultra-compliant materials for semiconductor devices, pressure sensors, visible light, UV and IR absorbing/reflective materials to block photons from the dies, stiff polymers to encapsulate the interconnects and/or vias, and/or transparent materials.

For some embodiments, the fan out package 500 may further include a plurality of solder balls 534 that are disposed on and coupled to the bottom surfaces 520b of the redistribution layers 520. For example, the solder balls 534 may be used on a BGA. Note that other methods of connectivity packaging may also be used such as PGA or LGA. For some embodiments, the fan out package 500 may then be disposed on another component, such as another substrate which may include a PCB, a package substrate, an interposer, and/or a motherboard.

Note that the package substrate 500 of FIGS. 5A-5B may include fewer or additional packaging components based on the desired packaging design.

FIG. 6 is an illustration of a plan view of a fan out package 600 having a plurality of dies 610-611, a mold layer 630, a plurality of vias 643, and a plurality of interconnects 642, according to one embodiment. In particular, as shown by the top view of FIG. 6, the fan out package 600 includes the vias 643 and the interconnects 642 (also referred to as the RDL interconnects) which are implemented as a shared grounded network between the dies 610-611.

In some embodiments, the fan out package 600 includes disposing the mold layer 630 on and around the top surfaces 610a and 611a of the dies 610-611, the vias 643, and the interconnects 642, where one or more of the vias 643 and the interconnects 642 are disposed and shared between the two dies 610-611. According to one embodiment, the fan out package 600 may be similar to the WLCSP 100 of FIG. 1, the FCCSPs 200 and 300 of FIGS. 2-3, and the fan out packages 400 and 500 of FIGS. 4-5; however the fan out package 600 illustrates the vias 643 and the interconnects 642 disposed and shared between the two dies 610-611—and disposed above and adjacently to the dies 610-611—prior to (i) optionally disposing a dielectric over the top surfaces 610a and 611a of the dies 610-611, the vias 643, and the interconnects 642 (i.e., the dielectric may be used as to protect the vias 643 and the interconnects 642), (ii) dicing the fan out package 600 into individual dies, where the individual dies may then include half-vias and interconnects disposed above and on the edges of the individual dies, and (iii) disposing a shield to surround the individual dies and the respective components (e.g., the half-via, the interconnects, the mold layer, the redistribution layer, the dielectric (if needed), and so on). Note that the one or more components of the fan out package 600 may be similar to the one or more components of the WLCSP 100 of FIG. 1, the FCCSPs 200 and 300 of FIGS. 2-3, and the fan out packages 400 and 500 of FIGS. 4-5 as described above.

For some embodiments, the fan out package 600 includes disposing the vias 643 on the edges of the dies 610-611 and between the dies 610-611. Additionally, the fan out package 600 includes disposing (or forming) the interconnects 643 above and/or between the dies 610-611, where the interconnects 643 are coupled to the vias 642 to form a redistribution routing layer(s) that may be used for grounding (i.e., the coupled vias and interconnects 642-643 form a grounding shared network between the dies 610-611). Note that only the two dies 610-611 are shown to simplify the illustration of FIG. 6, however the vias and the interconnects (e.g., the vias 642 and the interconnects 643) may be disposed and coupled between these two dies and other additional dies if needed.

In some embodiments, the vias 643 may be implemented and shared between the dies 610-611 to ensure improved coupling, for example, with the redistribution layers and the subsequently disposed shield, where the vias 643 may be formed deep within the mold layer 630 as a via, a plug, a pillar, and/or a trench. As described above, the vias 643 and the interconnects 642 of the fan out package 600 may be subsequently diced on the interface 699 between the die 610 region and the die 611 region, where, after cutting/dicing the vias 643 and the interconnects 642 in half, the vias 643 may be similar to the vias 440 of FIG. 4 and the interconnects 642 may also have one or more exposed surfaces through the mold layer 630. Note that the dicing of the vias 643 and the interconnects 642 on the interface 699 enables one or more vias and interconnects to have at least one or more exposed surfaces which may be used to subsequently couple the exposed surfaces of the diced interconnects and vias 642-643 to a subsequently disposed shield (e.g., as shown in FIG. 4).

In some embodiments, the vias 643 and the interconnects 642 may be formed by a laser process, or by adding an additional mask process to protect the dies 610-611 and then selectively etching the required structures within the mold layer 630. For some embodiments, the vias 643 and the interconnects 642 may be formed of one or more conductive materials, such as Cu, Ni, Sn, Au, Ag, Al, an Al alloy, W, Ti, Ta, TiN, TaN, and/or the like. Note that the vias 643 and the interconnects 642 may be a single, continuous conductive component, or two or more separate, coupled conductive components.

For some embodiments, the interconnects 642 may be disposed directly above the top surfaces 610a and 611a of the dies 610-611, accordingly the interconnects 642 may then be positioned (and are running) parallel to the top surfaces 610a and 611a of the dies 610-611. In other embodiments, the interconnects 642 may be disposed above the top surfaces 610a and 611a of the dies 610-611, but may have the mold layer 630 sandwiched (or disposed) between the top surfaces 610a and 611a of the dies 610-611 and the interconnects 642. In these embodiments, the interconnects 642 may be sandwiched (or embedded) between the mold layer 630 and, for example, the dielectric layer, which may be subsequently disposed over the interconnects 642 for increased protection against corrosion.

Additionally, in one embodiment, the interconnects 642 may have approximately the same length (or width). However, in other embodiments, the interconnects 642 may have one or more interconnects that have different lengths (or widths). Note that, in one embodiment, the interconnects 642 may have one or more interconnects that are disposed, routed, and shared between three or more dies (i.e., the interconnects 642 are not limited to being disposed, routed, and shared by only two dies such as the dies 610-611).

In some embodiment, the fan out package 600 includes the mold layer 630 disposed on and around the dies 610-611, the vias 643, and the interconnects 642, where the mold layer 630 may be disposed over the vias 643 and the interconnects 642. Note that, in one embodiment, the mold layer 630 may be disposed to completely embed (or cover) the vias 643 and the interconnects 642, or, in another embodiment, one or more portions of the vias 643 and the interconnects 642 may be exposed and then disposed (or covered) by a dielectric layer. For one embodiment, the mold layer 630 is made of an epoxy with one or more filler materials. According to some embodiments, the one or more materials for the mold layer 630 may include, but are not limited to, ultra-compliant materials for semiconductor devices, pressure sensors, visible light, UV and IR absorbing/reflective materials to block photons from the dies, stiff polymers to encapsulate the interconnects and/or vias, and/or transparent materials.

Note that the package substrate 600 may include fewer or additional packaging components based on the desired packaging design.

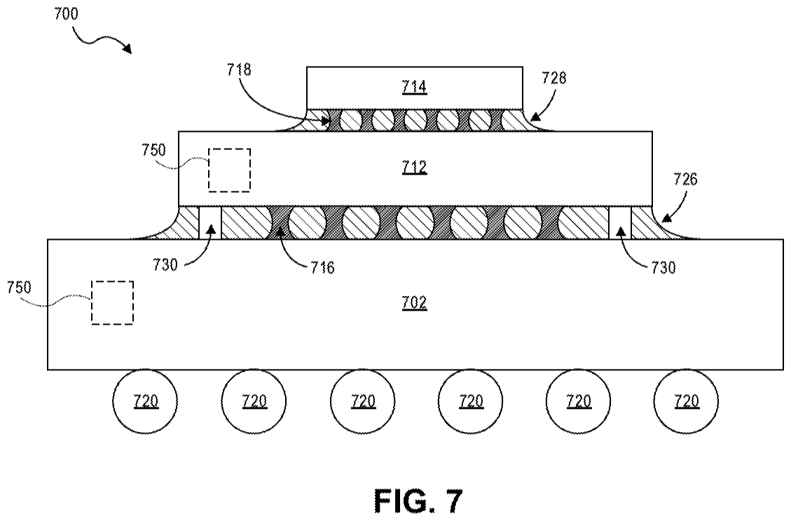

FIG. 7 is an illustration of a cross-sectional view of a semiconductor packaged system 700 including a die 714, a substrate 712, a package substrate 702, and one or more semiconductor packages 750, according to one embodiment. Furthermore, the semiconductor packaged system 700 includes the substrate 712 and the package substrate 702, where both and/or one of the substrate 712 and the package substrate 702 may include the semiconductor package(s) 750.

For one embodiment, the semiconductor package 700 may implement the substrate 712 and/or the package substrate 702 to include the semiconductor package 750, where the semiconductor package 750 may include a WLCSP, a FCCSP, and/or a fan out package as described above (e.g., the WLCSP 100 of FIG. 1, the FCCSPs 200 and 300 of FIGS. 2-3, and the fan out packages 400, 500, and 600 of FIGS. 4-6). In some embodiments, the semiconductor package 750 may include, but is not limited to, a shield, one or more dies, one or more interconnects, a dielectric, a redistribution layer, a substrate, and/or one or more RDL interconnects as described above. Accordingly, in one embodiment, the one or more semiconductor packages 750 may be similar to the semiconductor packages as described above in FIGS. 1-6. Note that the semiconductor package 700 is not limited to the illustrated semiconductor packaged system, and thus may be designed/formed with fewer, alternate, or additional packaging components and/or with different interconnecting structures.

According to one embodiment, the semiconductor package 700 is merely one example of an embodiment of a semiconductor packaged system. For one embodiment, the semiconductor package 700 may include a LGA package, BGA package, and/or a PGA package. For one embodiment, the die 714 is coupled to the substrate 712 (e.g., an interposer) via one or more bumps/joints formed from respective microbumps. As described above, a solder joint formed by soldering of a microbump according to an embodiment may itself be referred to as a “bump” and/or a “microbump.” Additionally, for other embodiments, the die 714, the substrate 712, and the package substrate 702 may be coupled using anisotropic conductive film (ACF). For one embodiment, the substrate 712 may be, but is not limited to, a silicon interposer and/or a die with through silicon vias (TSVs). For an alternate embodiment, the semiconductor package 700 may omit the interposer/substrate 712.

For some embodiments, the semiconductor package 700 may have the die 714 disposed on the interposer 712, where both the stacked die 714 and interposer 712 are disposed on a package substrate 702. According to some embodiments, the package substrate 702 may include, but is not limited to, a package, a substrate, a PCB, and a motherboard. For one embodiment, the package substrate 702 is a PCB. For one embodiment, the PCB is made of an FR-4 glass epoxy base with thin copper foil laminated on both sides. For certain embodiments, a multilayer PCB can be used, with pre-preg and copper foil used to make additional layers. For example, the multilayer PCB may include one or more dielectric layers, where each dielectric layer can be a photosensitive dielectric layer. For some embodiments, holes may be drilled in the PCB 702. For one embodiment, the PCB 702 may also include conductive layers that comprise copper lines/traces, metallic pads, vias, via pads, planes, and/or holes.

For one embodiment, the die 714 may include, but is not limited to, a semiconductor die, an electronic device (e.g., a wireless device), an integrated circuit, a CPU, a microprocessor, a PCH, a memory, and/or a FPGA. The die 714 may be formed from a material such as silicon and have circuitry thereon that is to be coupled to the interposer 712. Although some embodiments are not limited in this regard, the package substrate 702 may in turn be coupled to another body, for example, a computer motherboard. One or more connections between the package substrate 702, the interposer 712, and the die 714—e.g., including some or all of bumps 716, 718, and 720—may include one or more interconnect structures and underfill layers 726 and 728. In some embodiments, these interconnect structures (or connections) may variously comprise an alloy of nickel, palladium, and tin (and, in some embodiments, copper).

Connections between the package substrate 702 and another body may be made using any suitable structure, such as the illustrative bumps 720 shown. The package substrate 702 may include a variety of electronic structures formed thereon or therein. The interposer 712 may also include electronic structures formed thereon or therein, which may be used to couple the die 714 to the package substrate 702. For one embodiment, one or more different materials may be used for forming the package substrate 702 and the interposer 712. In certain embodiments, the package substrate 702 is an organic substrate made up of one or more layers of polymer base material, with conducting regions for transmitting signals. In certain embodiments, the interposer 712 is made up of a ceramic base material including metal regions for transmitting signals. Although some embodiments are not limited in this regard, the semiconductor package 700 may include gap control structures 730—e.g., positioned between the package substrate 702 and the interposer 712. Such gap control structures 730 may mitigate a change in the height of the gap between the package substrate 702 and the interposer 712, which otherwise might occur during reflowing while die 714 is attached to interposer 712. Note that the semiconductor package 700 includes an underfill material 728 between the interposer 712 and the die 714, and an underflow material 726 between the package substrate 702 and the interposer 712. For one embodiment, the underfill materials (or layers) 726 and 728 may be one or more polymers that are injected between the layers. For other embodiments, the underfill materials may be molded underfills (MUF).

Note that the semiconductor package 700 may include fewer or additional packaging components based on the desired packaging design.

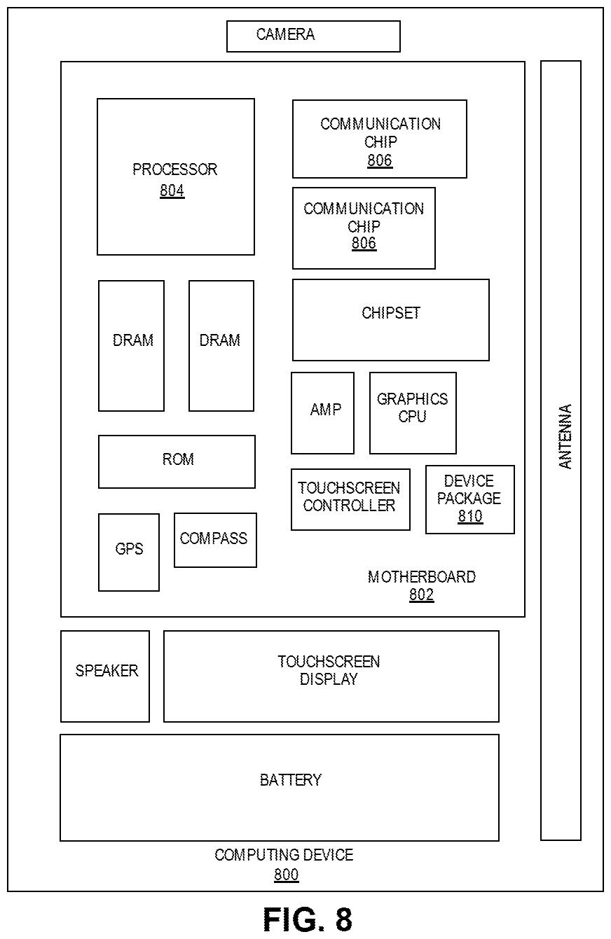

FIG. 8 is an illustration of a schematic block diagram illustrating a computer system 800 that utilizes a device package 810 (or a semiconductor package) having a shield surrounding a plurality of dies, a plurality of interconnects, a dielectric, and a redistribution layer, according to one embodiment. FIG. 8 illustrates an example of computing device 800. Computing device 800 houses motherboard 802. For one embodiment, motherboard 802 may be similar to the substrate of FIG. 4 (e.g., the substrate 402 of FIG. 4). Motherboard 802 may include a number of components, including but not limited to processor 804, device package 810 (or semiconductor package), and at least one communication chip 806. Processor 804 is physically and electrically coupled to motherboard 802. For some embodiments, at least one communication chip 806 is also physically and electrically coupled to motherboard 802. For other embodiments, at least one communication chip 806 is part of processor 804.

Depending on its applications, computing device 800 may include other components that may or may not be physically and electrically coupled to motherboard 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 806 enables wireless communications for the transfer of data to and from computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

Processor 804 of computing device 800 includes an integrated circuit die packaged within processor 804. Device package 810 may be, but is not limited to, a semiconductor package, a substrate, a package substrate, and/or a PCB. In particular, device package 810 may include a WLCSP, a FCCSP, and/or a fan out package, where the device package 810 includes a shield that surrounds one or more components such as dies, dielectrics, mold layers, vias, RDL interconnects, redistribution layers, solder balls, etc. (e.g., as illustrated in FIGS. 1-6)—or any other components from the figures described herein.

Note that device package 810 may be a single component/device, a subset of components, and/or an entire system, as the materials, features, and components may be limited to device package 810 and/or any other component of the computing device 800 that may need improved shielding techniques as described herein (e.g., the motherboard 802, the processor 804, and/or any other component of the computing device 800 that may need WLCSPs, FCCSPs, and/or fan out packages as described herein).

For certain embodiments, the integrated circuit die may be packaged with one or more devices on a package substrate that includes a thermally stable RFIC and antenna for use with wireless communications and the device package, as described herein, to reduce the z-height of the computing device. The term “processor” may refer to any device or portion of a device that processes electronic data from registers and/or memory to transform that electronic data into other electronic data that may be stored in registers and/or memory.

At least one communication chip 806 also includes an integrated circuit die packaged within the communication chip 806. For some embodiments, the integrated circuit die of the communication chip may be packaged with one or more devices on a package substrate that includes one or more device packages, as described herein.

In the foregoing specification, embodiments have been described with reference to specific exemplary embodiments thereof. It should be borne in mind, however, that all of these and similar terms are to be associated with the appropriate physical quantities and are merely convenient labels applied to these quantities. It will be evident that various modifications may be made thereto without departing from the broader spirit and scope. The specification and drawings are, accordingly, to be regarded in an illustrative sense rather than a restrictive sense.

The following examples pertain to further embodiments. The various features of the different embodiments may be variously combined with some features included and others excluded to suit a variety of different applications.

The following examples pertain to further embodiments:

Example 1: a wafer level chip scale package (WLCSP), comprising: a first doped region on a second doped region, wherein the first doped region has a plurality of sidewalls, a top surface, and a bottom surface that is opposite to the top surface; a dielectric on a redistribution layer, wherein the dielectric is between the redistribution layer and the first and second doped regions; and a shield over the first and second doped regions, the dielectric, and the redistribution layer, wherein the shield includes a plurality of surfaces, and wherein at least one of the plurality of surfaces of the shield is on the top surface of the first doped region.

### Example 2

The WLCSP of Example 1, further comprising a plurality of interconnects coupled to the second doped region and the redistribution layer.

### Example 3

The WLCSP of Example 1-2, wherein the shield is a conductive shield, wherein the conductive shield is conductively coupled to ground, and wherein the shield is directly coupled to the redistribution layer and the first doped region.

### Example 4

The WLCSP of Example 1-3, further comprising a plurality of solder balls coupled to the redistribution layer.

### Example 5

The WLCSP of Example 1-4, wherein the first and second doped regions include a plurality of highly doped n-type materials.

### Example 6

The WLCSP of Example 1-5, wherein the plurality of surfaces of the shield include a top surface and one or more sidewalls.

### Example 7

The WLCSP of Example 1-6, wherein the shield is a five-sided shield.

### Example 8

The WLCSP of Example 1-7, wherein the top surface of the shield is directly disposed on the top surface of the first doped region, and wherein the one or more sidewalls of the shield are directly disposed on the plurality of the sidewalls of the first doped region.

### Example 9

A flip chip scale package (FCCSP), comprising: a die on a substrate, wherein the die has a plurality of sidewalls, a top surface, and a bottom surface that is opposite to the top surface; a mold layer over the die and the substrate; and a shield over the die, the mold layer, and the substrate, wherein the shield includes a plurality of surfaces, and wherein at least one of the plurality of surfaces of the shield is directly coupled to the top surface of the die.

### Example 10

The FCCSP of Example 9, further comprising: a plurality of interconnects directly coupled to the top surface of the die and the shield, wherein the plurality of interconnects include through mold vias; and a plurality of second solder balls coupled to the substrate.

### Example 11

The FCCSP of Example 9-10, wherein the die further comprises: a first doped region on a second doped region, wherein the first doped region has a plurality of first sidewalls, a top first surface, and a bottom first surface that is opposite to the top first surface; a dielectric on a redistribution layer, wherein the dielectric is between the redistribution layer and the first and second doped regions; a plurality of interconnects coupled to the second doped region and the redistribution layer; and a plurality of first solder balls coupled to the redistribution layer and the substrate.

### Example 12

The FCCSP of Example 9-11, wherein the mold layer is directly disposed on the plurality of sidewalls of the die or the top surface of the die.

### Example 13

The FCCSP of Example 9-12, wherein the shield is a conductive shield, wherein the conductive shield is conductively coupled to ground, and wherein the shield is directly coupled to the substrate and the die.

### Example 14

The FCCSP of Example 9-13, wherein the first and second doped regions include a plurality of highly doped n-type materials.

### Example 15

The FCCSP of Example 9-14, wherein the plurality of surfaces of the shield include a top surface and one or more sidewalls.

### Example 16

The FCCSP of Example 9-15, wherein the shield is a five-sided shield.

### Example 17

The FCCSP of Example 9-16, wherein the top surface of the shield is directly disposed on the top surface of the die, and wherein the one or more sidewalls of the shield are directly disposed on the mold layer and the substrate.

### Example 18

The FCCSP of Example 9-17, wherein the mold layer is directly disposed on the top surface of the die and the plurality of interconnects, wherein the at least one of the plurality of surfaces of the shield is directly disposed on the plurality of interconnects that are directly coupled to the top surface of the die, and wherein the other surfaces of the plurality of surfaces of the shield are directly disposed on the mold layer and the substrate.

### Example 19

A fan out package, comprising: a die on a redistribution layer, wherein the die has a plurality of sidewalls, a top surface, and a bottom surface that is opposite to the top surface; a plurality of vias adjacent to at least two of the plurality of sidewalls of the die; a mold layer over the die, the plurality of vias, and the redistribution layer; and a shield over the die, the mold layer, and the redistribution layer, wherein the shield includes a plurality of surfaces, and wherein the shield is directly coupled to the plurality of vias.

### Example 20

The fan out package of Example 19, wherein the plurality of vias are embedded within the mold layer, wherein the plurality of vias have one or more outer edge surfaces directly coupled to the shield, and wherein the plurality of vias include conductive vias, conductive trenches, conductive plugs, or conductive pillars.

### Example 21

The fan out package of Example 19-20, wherein the mold layer is directly disposed on the plurality of sidewalls of the die or the top surface of the die.

### Example 22

The fan out package of Example 19-21, wherein the shield is a conductive shield, wherein the conductive shield is conductively coupled to ground, and wherein the shield is coupled to the redistribution layer by the plurality of vias.

### Example 23

The fan out package of Example 19-22, further comprising: a plurality of redistribution layer interconnects coupled to the plurality of vias, wherein the plurality of redistribution layer interconnects are disposed above the top surface of the die; and a plurality of solder balls coupled to the redistribution layer.

### Example 24

The fan out package of Example 19-23, wherein the shield is a five-sided shield, wherein the plurality of surfaces of the shield include a top surface and one or more sidewalls, wherein the mold layer is disposed between the top surface of the die and the top surface of the shield, and wherein the one or more sidewalls of the shield are directly disposed on the mold layer and the one or more outer edge surfaces of the vias.

### Example 25

The fan out package of Example 19-24, further comprising a conductive layer coupled to the plurality of vias and the redistribution layer, wherein the plurality of redistribution layer interconnects are conductively coupled to the plurality of vias, the conductive layer, the shield, and the redistribution layer.

In the foregoing specification, methods and apparatuses have been described with reference to specific exemplary embodiments thereof. It will be evident that various modifications may be made thereto without departing from the broader spirit and scope. The specification and drawings are, accordingly, to be regarded in an illustrative sense rather than a restrictive sense.

What is claimed is:

1. A wafer level chip scale package (WLCSP), comprising:
a first doped region on a second doped region, wherein the first doped region has a plurality of sidewalls, a top surface, and a bottom surface that is opposite to the top surface;
a dielectric on a redistribution layer, wherein the dielectric is between the redistribution layer and the first and second doped regions; and
a shield over the first and second doped regions, the dielectric, and the redistribution layer, wherein the shield includes a plurality of surfaces, and wherein at least one of the plurality of surfaces of the shield is on the top surface of the first doped region.

2. The WLCSP of claim 1, further comprising: a plurality of interconnects coupled to the second doped region and the redistribution layer.

3. The WLCSP of claim 1, wherein the shield is a conductive shield, wherein the conductive shield is conductively coupled to ground, and wherein the shield is directly coupled to the redistribution layer and the first doped region.

4. The WLCSP of claim 1, further comprising: a plurality of solder balls coupled to the redistribution layer.

5. The WLCSP of claim 1, wherein the first and second doped regions include a plurality of highly doped n-type materials.

6. The WLCSP of claim 1, wherein the plurality of surfaces of the shield include a top surface and one or more sidewalls.

7. The WLCSP of claim 1, wherein the shield is a five-sided shield.

8. The WLCSP of claim 6, wherein the top surface of the shield is directly disposed on the top surface of the first doped region, and wherein the one or more sidewalls of the shield are directly disposed on the plurality of the sidewalls of the first doped region.

9. A flip chip chip scale package (FCCSP), comprising:
a die on a substrate, wherein the die has a plurality of sidewalls, a top surface, and a bottom surface that is opposite to the top surface;
a mold layer over the die and the substrate; and
a shield over the die, the mold layer, and the substrate, wherein the shield includes a plurality of surfaces, and wherein at least one of the plurality of surfaces of the shield is directly coupled to the top surface of the die.

10. The FCCSP of claim 9, further comprising:
a plurality of interconnects directly coupled to the top surface of the die and the shield, wherein the plurality of interconnects include through mold vias; and
a plurality of second solder balls coupled to the substrate.

11. The FCCSP of claim 9, wherein the die further comprises:
a first doped region on a second doped region, wherein the first doped region has a plurality of first sidewalls, a top first surface, and a bottom first surface that is opposite to the top first surface;
a dielectric on a redistribution layer, wherein the dielectric is between the redistribution layer and the first and second doped regions;
a plurality of interconnects coupled to the second doped region and the redistribution layer; and
a plurality of first solder balls coupled to the redistribution layer and the substrate.

12. The FCCSP of claim 9, wherein the mold layer is directly disposed on the plurality of sidewalls of the die or the top surface of the die.

13. The FCCSP of claim 9, wherein the shield is a conductive shield, wherein the conductive shield is conductively coupled to ground, and wherein the shield is directly coupled to the substrate and the die.

14. The FCCSP of claim 11, wherein the first and second doped regions include a plurality of highly doped n-type materials.

15. The FCCSP of claim 9, wherein the plurality of surfaces of the shield include a top surface and one or more sidewalls.

16. The FCCSP of claim 9, wherein the shield is a five-sided shield.

17. The FCCSP of claim 15, wherein the top surface of the shield is directly disposed on the top surface of the die, and wherein the one or more sidewalls of the shield are directly disposed on the mold layer and the substrate.

18. The FCCSP of claim 10, wherein the mold layer is directly disposed on the top surface of the die and the plurality of interconnects, wherein the at least one of the plurality of surfaces of the shield is directly disposed on the plurality of interconnects that are directly coupled to the top surface of the die, and wherein the other surfaces of the plurality of surfaces of the shield are directly disposed on the mold layer and the substrate.

19. A fan out package, comprising:
a die on a redistribution layer, wherein the die has a plurality of sidewalls, a top surface, and a bottom surface that is opposite to the top surface;
a plurality of vias adjacent to at least two of the plurality of sidewalls of the die;
a mold layer over the die, the plurality of vias, and the redistribution layer; and
a shield over the die, the mold layer, and the redistribution layer, wherein the shield includes a plurality of surfaces, and wherein the shield is directly coupled to the plurality of vias.

20. The fan out package of claim 19, wherein the plurality of vias are embedded within the mold layer, wherein the plurality of vias have one or more outer edge surfaces directly coupled to the shield, and wherein the plurality of vias include conductive vias, conductive trenches, conductive plugs, or conductive pillars.

21. The fan out package of claim 19, wherein the mold layer is directly disposed on the plurality of sidewalls of the die or the top surface of the die.

22. The fan out package of claim 19, wherein the shield is a conductive shield, wherein the conductive shield is conductively coupled to ground, and wherein the shield is coupled to the redistribution layer by the plurality of vias.

23. The fan out package of claim 19, further comprising:
a plurality of redistribution layer interconnects coupled to the plurality of vias, wherein the plurality of redistribution layer interconnects are disposed above the top surface of the die; and
a plurality of solder balls coupled to the redistribution layer.

24. The fan out package of claim 20, wherein the shield is a five-sided shield, wherein the plurality of surfaces of the shield include a top surface and one or more sidewalls, wherein the mold layer is disposed between the top surface of the die and the top surface of the shield, and wherein the one or more sidewalls of the shield are directly disposed on the mold layer and the one or more outer edge surfaces of the vias.

25. The fan out package of claim 23, further comprising: a conductive layer coupled to the plurality of vias and the redistribution layer, wherein the plurality of redistribution layer interconnects are conductively coupled to the plurality of vias, the conductive layer, the shield, and the redistribution layer.
